(19) United States
(12) Patent Application Publication
(10) Pub. No.: US 2025/0244756 A1
(43) Pub. Date: Jul. 31, 2025

(54) INFORMATION PROCESSING METHOD, COMPUTER PROGRAM, AND INFORMATION PROCESSING APPARATUS

(71) Applicant: Tokyo Electron Limited, Tokyo (JP)

(72) Inventors: Ryoji ANZAKI, Tokyo (JP); Kei SANO, Austin, TX (US)

(73) Assignee: Tokyo Electron Limited, Tokyo (JP)

(21) Appl. No.: 19/183,135

(22) Filed: Apr. 18, 2025

Related U.S. Application Data
(63) Continuation of application No. PCT/JP2023/038342, filed on Oct. 24, 2023.

(30) Foreign Application Priority Data
Oct. 26, 2022 (JP) 2022-171576

(51) Int. Cl. G05B 19/418

(52) U.S. Cl. CPC G05B 19/41885; G05B 2219/34465

(57) ABSTRACT

Provided are an information processing method, a computer program, and an information processing apparatus that can be expected to effectively utilize data obtained from a target apparatus. An information processing method according to the present embodiment is performed by an information processing apparatus and includes acquiring time series observed data regarding a target apparatus, and calculating a first parameter and a second parameter of a model that predicts time evolution data of the observed data based on the observed data, by dynamic mode decomposition based on the acquired observed data, in which the first parameter is a parameter relating to a transformation function for transforming the observed data into the time evolution data, and the second parameter is a parameter relating to a function of the observed data describing the time evolution data.

### CROSS-REFERENCE TO RELATED APPLICATIONS

This application is a bypass continuation application of international application No. PCT/JP2023/038342, having an international filing date of Oct. 24, 2023, and designating the United States, the international application being based upon and claiming the benefit of priority from Japanese Patent Application No. 2022-171576, filed on Oct. 26, 2022, the entire contents of each are incorporated herein by reference.

### TECHNICAL FIELD

The present disclosure relates to an information processing method, a computer program, and an information processing apparatus.

### BACKGROUND

Patent Document 1 proposes a state determination apparatus that generates a learning model by acquiring data related to an industrial machine, creating a plurality of partial time series data obtained by sliding time series data of physical quantities in data related to the industrial machine in a time axis direction based on the acquired data related to the industrial machine, extracting a plurality of learning data that include the plurality of partial time series data, and performing machine learning using the extracted learning data.

### CITATION LIST

### Patent Documents

Patent Literature 1: JP2020-128013A

### SUMMARY

The present disclosure is to provide an information processing method, a computer program, and an information processing apparatus that can be expected to effectively utilize data obtained from a target apparatus.

One embodiment relates to an information processing method performed by an information processing apparatus, the information processing method including: acquiring time series observed data regarding a target apparatus; and calculating a first parameter and a second parameter of a model that predicts time evolution data of the observed data based on the observed data, by dynamic mode decomposition based on the acquired observed data, in which the first parameter is a parameter relating to a transformation function for transforming the observed data into the time evolution data, and the second parameter is a parameter relating to a function of the observed data describing the time evolution data.

According to the present disclosure, it can be expected to effectively utilize the data obtained from the target apparatus.

### BRIEF DESCRIPTION OF DRAWINGS

FIG. 1 is a schematic diagram illustrating an overview of an information processing system according to the present embodiment.

FIG. 2 is a block diagram illustrating a configuration of an information processing apparatus according to the present embodiment.

FIG. 3 is a flowchart illustrating a procedure of parameter calculation processing performed by the information processing apparatus according to the present embodiment.

FIG. 4 is a flowchart illustrating a procedure of abnormality determination processing performed by the information processing apparatus according to the present embodiment.

FIG. 5 is a schematic diagram illustrating an overview of an information processing system according to a modification example.

FIG. 6 is a flowchart illustrating a procedure of parameter calculation processing performed by an information processing apparatus according to Modification Example 2.

### DETAILED DESCRIPTION

Hereinafter, a specific example of an information processing system according to the embodiment of the present disclosure will be described with reference to the drawings. The present disclosure is not limited to these examples, and is defined by the claims, and is intended to include all modifications within the meaning and scope equivalent to the claims.

### System Overview

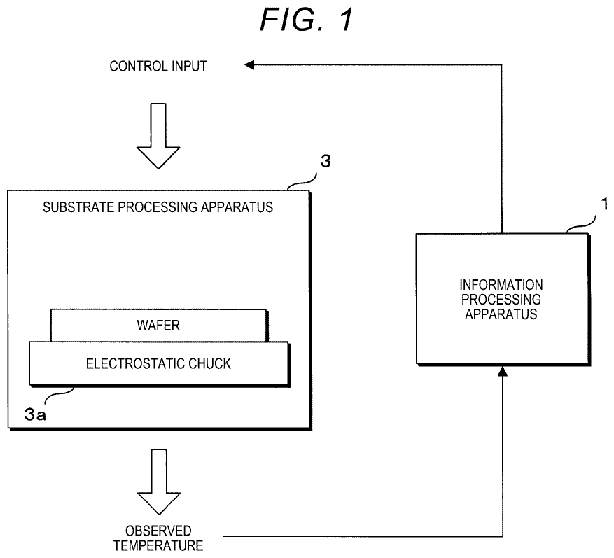

FIG. 1 is a schematic diagram illustrating an overview of the information processing system according to the present embodiment. The information processing system according to the present embodiment includes an information processing apparatus 1 and a substrate processing apparatus 3. The substrate processing apparatus 3 illustrated in the drawing is, for example, an apparatus such as a process chamber that performs processing such as etching on a wafer of a semiconductor. The substrate processing apparatus 3 includes, for example, an electrostatic chuck 3a for electrostatically fixing the wafer that is a processing target, a temperature control device (not illustrated) for controlling a temperature of the wafer, such as a chiller (cooling device) and/or a heater (heating device), and a sensor (not illustrated) that measures the temperature of the wafer.

The information processing apparatus 1 is an apparatus that performs control, monitoring, and the like of the operation of the substrate processing apparatus 3, and performs, in the present embodiment, temperature control of the substrate processing apparatus 3. The information processing apparatus 1 is connected to the substrate processing apparatus 3 through, for example, a communication line, a signal line, or the like, and supplies control input data to the temperature control device of the substrate processing apparatus 3, and acquires observed temperature data obtained by sensors of the substrate processing apparatus 3. The information processing apparatus 1 determines the control input data based on the observed temperature data acquired from the substrate processing apparatus 3, and supplies the control input data to the temperature control device of the substrate processing apparatus 3. Accordingly, the temperature of the wafer fixed to the electrostatic chuck 3a of the substrate processing apparatus 3 is controlled so that a desired temperature is maintained.

Further, in the present embodiment, the information processing apparatus 1 samples and acquires the control input data and the observed temperature data at a predetermined frequency, such as once a second or once a minute, when the wafer is being processed in the substrate processing apparatus 3. The information processing apparatus 1 stores the acquired control input data and observed temperature data, in a database. In the present embodiment, the information processing apparatus 1 inputs a plurality of control values as control data to the temperature control device of the substrate processing apparatus 3. Further, the substrate processing apparatus 3 is provided with a plurality of temperature sensors in order to observe a temperature distribution of the wafer, and the information processing apparatus 1 acquires the temperatures at a plurality of locations of the wafer measured by the plurality of temperature sensors as the observed temperature data. Therefore, in the present embodiment, the control input data and the observed temperature data stored in the database by the information processing apparatus 1 are multi-dimensional (two or more dimensions) vector information. The numbers of dimensions of the control input data and the observed temperature data may not be equal. Any one or both of the control input data and the observed temperature data may be a one-dimensional scalar value.

In the present embodiment, after the processing on the wafer is completed, for example, the information processing apparatus 1 determines the presence or absence of an abnormality or the like with respect to the processing performed on the wafer, the operation of the substrate processing apparatus 3, or the like, based on time series data of the control input data and the observed temperature data stored in the database. In the present embodiment, the information processing apparatus 1 uses a method of “dynamic mode decomposition” in order to perform, for example, the determination of the presence or absence of the abnormality. The dynamic mode decomposition is a method of decomposing the time series data into a plurality of variation factors (modes), and a model that predicts the time series data can be generated by using the method of the dynamic mode decomposition. The generated model is a model that receives the observed data at a certain point in time as input, for example, and outputs a prediction value of a first derivative value of the observed data at a subsequent point in time. The information processing apparatus 1 can determine parameters of the model that outputs the prediction values by performing processing of the dynamic mode decomposition using the time series data stored in the database. The dynamic mode decomposition is a known analysis method (see, for example, “Jonathan H. Tu, Clarence W. Rowley, Dirk M. Luchtenburg, Steven L. Brunton, J. Nathan Kutz. On dynamic mode decomposition: Theory and applications. Journal of Computational Dynamics, 2014, 1 (2): 391-421.”), and thus the detailed description thereof will be omitted.

For example, in the example illustrated in FIG. 1, the information processing apparatus 1 performs processing of the “dynamic mode decomposition” based on the time series observed temperature data by the sensors of the substrate processing apparatus 3. In this way, the information processing apparatus 1 can generate a model that receives the observed temperature data at a certain point in time as input, and outputs a prediction value of the observed temperature data at a subsequent point in time or data obtained by performing some arithmetic processing on the observed temperature data (hereinafter, these pieces of data will be referred to as time evolution data of the observed temperature data). In a case of general dynamic mode decomposition, a model that receives the observed temperature data as input and outputs a prediction value of the first derivative value of the observed temperature data is often used.

In the information processing system according to the present embodiment, as the above-described model, a model that receives the observed temperature data as input and outputs, as the time evolution data, a prediction value of a derivative value of a non-integer order expressed by a fractional differential equation is adopted. The information processing apparatus 1 according to the present embodiment performs processing of determining an appropriate differential order under given conditions, using, as parameters, the parameters of the model calculated by the method of the dynamic mode decomposition, as well as the differential order of the fractional differential equation.

The model generated by the information processing apparatus 1 does not need to be configured to receive and output the observed temperature data acquired from the substrate processing apparatus 3. The model may receive and output data obtained by performing some arithmetic processing (pre-processing) on the observed temperature data, such as an average value or a derivative value of the observed temperature data, for example. For example, the model may be configured to receive, as input, an average value of the observed temperature data at a certain point in time and within a predetermined time period before the point in time. Further, for example, the model may be configured to receive, as input, a first derivative value of the observed temperature data at a certain point in time. In the present embodiment, the time evolution data output by the model is data expressed by the fractional differential equation, but the time evolution data output by the model is not limited thereto.

Further, in the present embodiment, the information processing apparatus 1 uses a method of “dynamic mode decomposition with control input” in which the time series data of the control input can be additionally handled in the dynamic mode decomposition. By using the method of the dynamic mode decomposition with control input, the information processing apparatus 1 can generate a model that receives the control input data and the observed temperature data at a certain point in time as input, for example, and outputs the prediction value of the time evolution data of the observed temperature data at a subsequent point in time. The method of the dynamic mode decomposition with control input is a known analysis method (see, for example, “Joshua L. Proctor, Steven L. Brunton, J. Nathan Kutz. “Dynamic mode decomposition with control”, Sep. 24, 2014”), and thus the detailed description thereof will be omitted.

In the present embodiment, the information processing apparatus 1 performs processing of the “dynamic mode decomposition with control input” based on, for example, the control input data with respect to the substrate processing apparatus 3 and the observed temperature data from the substrate processing apparatus 3. In this way, the information processing apparatus 1 can generate a model that receives the control input data and the observed temperature data at a certain point in time as input, and outputs the prediction value of the time evolution data of the observed temperature data at a subsequent point in time. The control input data input to the model may be data obtained by performing some arithmetic processing on the data input to the substrate processing apparatus 3, such as an average value or a first derivative value, similarly to the model that outputs the prediction value of the observed temperature data. Even when the “dynamic mode decomposition” is simply described, the following description includes “dynamic mode decomposition with control input”.

The information processing apparatus 1 performs the dynamic mode decomposition with control input based on the control input data and the observed temperature data acquired when the substrate processing apparatus 3 is performing processing on one wafer and stored in the database. In this way, the information processing apparatus 1 can calculate values of internal parameters of the model that receives the control input data and the observed temperature data at a certain point in time as input, and outputs the prediction value of the time evolution data of the observed temperature data at a subsequent point in time. For example, the time evolution data is data expressed by a fractional differential equation, and the internal parameters of the model calculated by the information processing apparatus 1 include the differential order of the fractional differential equation. The information processing apparatus 1 compares the obtained parameters of the model with, for example, the parameters of the model determined using data collected for normally processed wafers or the parameters of the model determined using data collected when the abnormality occurs in the processing. With this configuration, the information processing apparatus 1 can determine the presence or absence of the abnormality with respect to the wafer processed this time.

### Apparatus Configuration

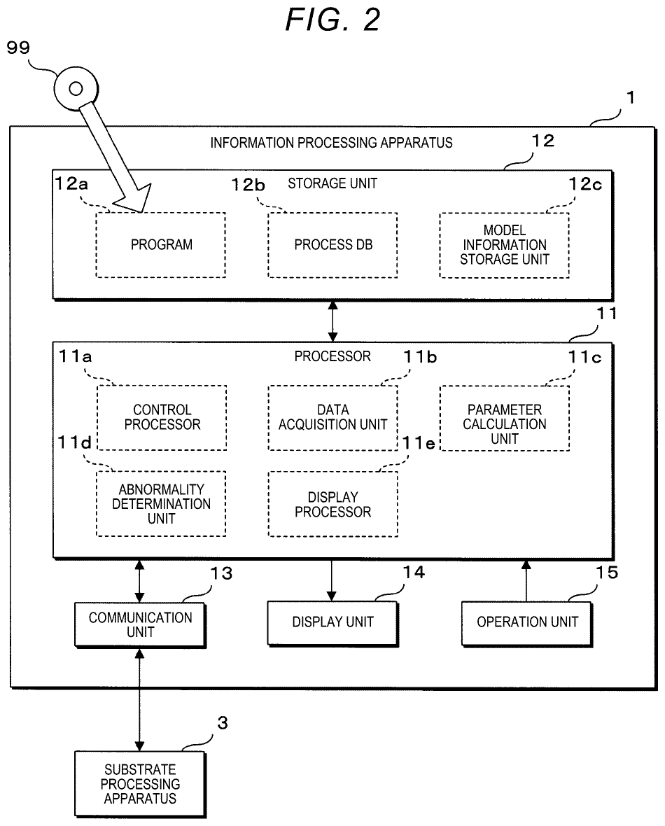

FIG. 2 is a block diagram illustrating a configuration of the information processing apparatus 1 according to the present embodiment. The information processing apparatus 1 according to the present embodiment includes a processor 11, a storage unit 12, a communication unit 13, a display unit 14, an operation unit 15, and the like. In the present embodiment, an example will be described in which a process is performed by one information processing apparatus 1. Meanwhile, the process of the information processing apparatus 1 may be distributed and performed by a plurality of apparatuses.

The processor 11 is configured by using an arithmetic processing apparatus such as a central processing unit (CPU), a micro-processing unit (MPU), a graphics processing unit (GPU), or a quantum processor, a read only memory (ROM), a random access memory (RAM), and the like. The processor 11 reads and executes a program 12a stored in the storage unit 12, thereby performing various processing such as processing of controlling the operation of the substrate processing apparatus 3 and processing of detecting the abnormality or the like in the substrate processing apparatus 3. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The storage unit 12 is configured by using, for example, a large-capacity storage apparatus such as a hard disk. The storage unit 12 stores various types of programs to be executed by the processor 11 and various types of data necessary for the process of the processor 11. In the present embodiment, the storage unit 12 stores the program 12a to be executed by the processor 11. Further, the storage unit 12 includes a process DB 12b that stores and accumulates the control input data and the observed temperature data, and a model information storage unit 12c that stores the parameters and the like of the model generated by the processing of the dynamic mode decomposition using these pieces of data.

In the present embodiment, the program (computer program, program product) 12a is provided in a form recorded on a recording medium 99 such as a memory card or an optical disc. The information processing apparatus 1 reads the program 12a from the recording medium 99, and stores the program 12a in the storage unit 12. However, for example, the program 12a may be written into the storage unit 12 during a manufacturing stage of the information processing apparatus 1. For example, as the program 12a, the information processing apparatus 1 may acquire those which are distributed by a remote server device or the like through communication. For example, the program 12a may be written into the storage unit 12 of the information processing apparatus 1 after a writing apparatus reads program recorded in the recording medium 99. The program 12a may be provided in the form of distribution through a network, or may be provided in the form recorded in the recording medium 99.

The process DB 12b in the storage unit 12 is a database that stores and accumulates data acquired by sampling the control input data with respect to the substrate processing apparatus 3 and the observed temperature data from the substrate processing apparatus 3 by the information processing apparatus 1. The process DB 12b stores the control input data and the observed temperature data, and various information such as, for example, a date and time of acquisition of the data and identification information of the wafer that is the processing target, in association with each other. Further, the process DB 12b may store the determination results of normal/abnormal (non-defective product/defective product) determined by measuring the characteristics of the wafer or the like after the processing by the substrate processing apparatus 3 is completed, for example.

The model information storage unit 12c stores information such as the parameters of the model obtained by the information processing apparatus 1 performing the processing of the dynamic mode decomposition using the control input data and the observed temperature data stored in the process DB 12b. In the present embodiment, the information processing apparatus 1 performs the processing of the dynamic mode decomposition using the acquired control input data and observed temperature data for each wafer processed by the substrate processing apparatus 3 to generate a model, and stores the parameters of the generated model in the model information storage unit 12c. The model information storage unit 12c may store the parameters of the model generated through the dynamic mode decomposition, and various information such as the date and time when the information is stored and the identification information of the wafer that is the processing target, in association with each other. Further, for example, the model information storage unit 12c may store information such as the result of the abnormality determination performed based on the parameters of the model.

The communication unit 13 is connected to the substrate processing apparatus 3 through a cable such as a communication line or a signal line, and transmits and receives data to and from the substrate processing apparatus 3 through the cable. In the present embodiment, the communication unit 13 transmits the control input data supplied from the processor 11 to the substrate processing apparatus 3. Further, the communication unit 13 receives the observed temperature data transmitted from the substrate processing apparatus 3, and supplies the received observed temperature data to the processor 11.

The display unit 14 is configured by using a liquid crystal display or the like, and displays various images, characters, and the like based on the process of the processor 11. In the present embodiment, the display unit 14 displays, for example, various information relating to an operation state of the substrate processing apparatus 3, and displays various information obtained through the dynamic mode decomposition.

The operation unit 15 receives a user operation and notifies the processor 11 of the received operation. For example, the operation unit 15 receives the user operation by an input device such as a mechanical button or a touch panel provided on a surface of the display unit 14. For example, the operation unit 15 may be an input device such as a mouse and a keyboard, and these input devices may be configured to be detachable from the information processing apparatus 1.

The storage unit 12 may be an external storage device connected to the information processing apparatus 1. The information processing apparatus 1 may be a multi-computer including a plurality of computers, or may be a virtual machine virtually constructed by software. In addition, the information processing apparatus 1 is not limited to the configuration described above, and does not need to include the display unit 14, the operation unit 15, and the like, for example.

In the information processing apparatus 1 of the present embodiment, the processor 11 reads and executes the program 12a stored in the storage unit 12, so that a control processor 11a, a data acquisition unit 11b, a parameter calculation unit 11c, an abnormality determination unit 11d, a display processor 11e, and the like are implemented as software-like functional units in the processor 11.

The control processor 11a performs processing of controlling the operation of the substrate processing apparatus 3 by performing, for example, the generation of the control input data and the transmission of the control input data to the substrate processing apparatus 3 in accordance with a predetermined semiconductor manufacturing procedure. For example, the control processor 11a supplies, as the control input data, data such as an amount of increase or decrease in temperature or an amount of operation of the apparatus, to the temperature control device such as one or more heaters and chillers provided in the substrate processing apparatus 3. In this way, the information processing apparatus 1 can perform the temperature control of the wafer processed by the substrate processing apparatus 3.

The data acquisition unit 11b performs processing of acquiring the control input data input by the control processor 11a to the substrate processing apparatus 3 and the observed temperature data measured by one or more temperature sensors provided in the substrate processing apparatus 3. The data acquisition unit 11b samples and acquires these pieces of data at predetermined intervals such as once per second or once per minute, for example. The data acquisition unit 11b stores the acquired control input data and observed temperature data and the date and time of acquisition of the data and the identification information of the wafer that is the processing target, in association with each other in the process DB 12b. The data acquisition unit 11b acquires data at predetermined intervals and stores the data in the process DB 12b, so that the time series data of the control input data and the observed temperature data are accumulated in the process DB 12b.

The parameter calculation unit 11c performs processing of calculating the parameters of the model by performing the processing of the dynamic mode decomposition based on the time series control input data and observed temperature data acquired by the data acquisition unit 11b and stored in the process DB 12b. In the present embodiment, the model receives the time series observed temperature data (and control input data) as input, and outputs the prediction value of the time evolution data of the observed temperature data. The time evolution data is data expressed by, for example, a fractional differential equation, and the parameters calculated by the parameter calculation unit 11c include the differential order of the fractional differential equation. Hereinafter, the differential order of the fractional differential equation peculiar to the information processing system according to the present embodiment will be referred to as a first parameter, and a parameter calculated by dynamic mode decomposition in the related art will be referred to as a second parameter. When the parameter is simply described, the parameter includes the first parameter and the second parameter. The parameter calculation unit 11c performs processing of calculating the first parameter and the second parameter of the model based on the time series control input data and observed temperature data stored in the process DB 12b.

In the present embodiment, for example, the user sets, in advance, a plurality of values to be candidates for the first parameter (the differential order of the fractional differential equation), and the parameter calculation unit 11c determines the optimum value from the set plurality of candidate values. For example, the parameter calculation unit 11c selects one candidate value from among the plurality of candidate values relating to the set first parameter, and determines the differential order of the fractional differential equation. The parameter calculation unit 11c can calculate the second parameter of the model by performing the dynamic mode decomposition based on the control input data and the observed temperature data stored in the process DB 12b. The parameter calculation unit 11c can determine the fractional differential equations for all the candidate values of the first parameter to perform the dynamic mode decomposition, thereby calculating the candidate values for the second parameter of the model corresponding to each candidate value. In this way, the parameter calculation unit 11c can obtain the candidate values for a plurality of sets of the first parameter and the second parameter.

Next, the parameter calculation unit 11c inputs the time series control input data and observed temperature data stored in the process DB 12b into the model, by using the model in which the respective candidate values of the first parameter and the second parameter are set. The parameter calculation unit 11c acquires the prediction values of the time evolution data of the observed temperature data output by the model. Based on the time series control input data and observed temperature data stored in the process DB 12b, the parameter calculation unit 11c calculates the derivative value of the non-integer order as the correct answer value of the time evolution data using the fractional differential equation for which the respective candidate values of the first parameter are set. Then, the parameter calculation unit 11c calculates an error between the prediction value and the correct answer value of the time evolution data. In this way, the parameter calculation unit 11c can calculate the error of the prediction value of the model with respect to each candidate value of the first parameter, and select the candidate value with the minimum error as the final first parameter.

For example, after the processing of one wafer by the substrate processing apparatus 3 is completed, the parameter calculation unit 11c reads, from the process DB 12b, the time series control input data and observed temperature data acquired and stored when processing the one wafer. The parameter calculation unit 11c calculates the first parameter and the second parameter of the model based on the read time series data. The parameter calculation unit 11c may perform the dynamic mode decomposition using only the observed temperature data, or the dynamic mode decomposition with control input using the control input data and the observed temperature data. Which dynamic mode decomposition is performed by the parameter calculation unit 11c may be determined, for example, by the user's selection. The parameter calculation unit 11c stores the calculated parameters of the model in the model information storage unit 12c.

The abnormality determination unit 11d performs processing of determining whether the abnormality has occurred when the substrate processing apparatus 3 processes the wafer corresponding to the time series data used for the dynamic mode decomposition, based on the parameters of the model calculated by the parameter calculation unit 11c. In the present embodiment, the time series data (control input data and observed temperature data) are collected in advance for each of a case where the wafer is normally processed and a case where the abnormality occurs. The dynamic mode decomposition is performed on the time series data for each processing on one wafer, and the processing of acquiring the parameters of the model is performed in advance. Based on the parameters at the time of normality and the parameters at the time of abnormality that are obtained in advance, a threshold of the parameters for distinguishing between the normality and the abnormality is determined in advance, and the threshold is stored as the determination condition in the storage unit 12 of the information processing apparatus 1. The abnormality determination unit 11d compares the parameter obtained through the dynamic mode decomposition of the parameter calculation unit 11c with a predetermined threshold to determine the presence or absence of an abnormality with respect to the processing performed on the wafer this time.

The parameter used by the abnormality determination unit 11d for the determination may be any one or both of the first parameter and the second parameter. Further, the second parameter may be a vector or matrix that includes a plurality of values. When the plurality of values are included in the parameter, a threshold for determining the abnormality may be determined for each of the plurality of values, for example. When it is determined that there is the abnormality by comparing the at least one value with the threshold, the abnormality determination unit 11d can determine that there is the abnormality in the processing performed on the wafer. Further, for example, one threshold may be set for the total value, the average value, or the like of the plurality of values included in the parameter. Further, for example, data obtained by associating a correct answer flag indicating the presence or absence of the abnormality with the parameter calculated based on the time series data collected in advance can be used as training data. The information processing apparatus 1 can generate an abnormality determination model that outputs the presence or absence of the abnormality in response to the input of the parameter, by performing so-called supervised machine learning using the training data. The abnormality determination unit 11d may perform the determination using this abnormality determination model.

The display processor 11e performs processing of displaying, on the display unit 14, various information such as various information relating to control processing by the control processor 11a and information relating to the abnormality determination result by the abnormality determination unit 11d. Further, in the present embodiment, the display processor 11e displays a message or the like that notifies the user of the abnormality when the abnormality determination unit 11d determines that the abnormality has occurred.

### Dynamic Mode Decomposition Introducing Fractional Differential Equation

The information processing system according to the present embodiment calculates the parameters of the model by the dynamic mode decomposition based on the time series control input data and observed temperature data acquired when the substrate processing apparatus 3 performs the processing on the wafer to determine the presence or absence of the abnormality. The model generated by the dynamic mode decomposition with control input in the related art is expressed by, for example, the following Equation (1).

$$\begin{matrix}[ Equation 1 ] & \\ \frac{dx}{dt} = Ax ( t ) + Bu ( t ) & ( 1 )\end{matrix}$$

Here, x(t) included in the right side of Equation (1) is an element of the vector X=[x(t₀), x(t₁), . . . , x(tₘ₋₁)] of the observed temperature data. u(t) is an element of the vector Y=[u(t₀), u(t₁), . . . , u(tₘ₋₁)] of the control input data. The left side of Equation (1) expresses the first derivative value of the observed temperature data. The coefficients A and B are the parameters (second parameters) of the model and are calculated by the dynamic mode decomposition. The model of Equation (1) can receive the observed temperature data and the control input data as input and output the prediction value of the first derivative value of the observed temperature data based on the determinations of coefficients A and B.

In the dynamic mode decomposition in the related art, as illustrated on the left side of Equation (1), a model that predicts the first derivative values of some time series data is often used. However, the prediction value of the model does not need to be the first derivative value, and need only be any value generated from the current and past values of the time series data. Based on this fact, Equation (1) is generalized to obtain the following Equation (2). In the present embodiment, Equation (2) will be referred to as a time evolution equation, and a model expressed by the time evolution equation will be referred to as a time evolution model. Further, data expressed by π(x)(t) on the left side of Equation (2) will be referred to as the time evolution data.

$$\begin{matrix}[ Equation 2 ] & \\ π ( x ) ( t ) = Ax ( t ) + Bu ( t ) & ( 2 )\end{matrix}$$

In Equation (2), a function for generating some value based on the observed temperature data x(t) is expressed by transformation π. Equation (1) is obtained by taking the transformation π as the first derivative d/dt. In the present embodiment, the transformation π is a linear transformation. That is, π(x)(t) is obtained by adding the weight w to the observed temperature data from the current time to the predetermined past point in time, respectively. When the transformation π is expressed by using a matrix D_{π} expressing weights, the above Equation (2) becomes the following Equation (3).

$$\begin{matrix}[ Equation 3 ] & \\ {XD}_{π} = AX + B Υ & ( 3 )\end{matrix}$$

The matrix D_{π} on the left side of Equation (3) is a matrix that includes a plurality of weights as components, and X corresponds to the observed temperature data. When the values of the respective components of the matrix D_{π} are determined, the calculation on the left side of Equation (3) can be performed. When the values on the left side of Equation (3) are determined, the coefficients A and B on the right side of Equation (3) can be calculated by the method of the dynamic mode decomposition with control input.

Therefore, in the information processing system according to the present embodiment, the transformation using the fractional differential equation is adopted as the transformation π. Based on Caputo differentiation, which is one of the definitions of the fractional differential equation, the transformation D^{(α)} corresponding to the fractional differential equation when the differential order is an α-th order, is expressed by the following Equation (4). Equation (4) is a definition when α is not a positive integer. Further, in Equation (4), m is a time-point number, and Dₘ⁽¹⁾ is an m×m matrix expression of an integer-1-th order derivative.

$$\begin{matrix}[ Equation 4 ] & \\ {𝒟}^{( α )} = {D}_{m}^{( ℓ )} [ {w}_{0}^{( ℓ - α )} , {w}_{1}^{( ℓ - α )} , … , {w}_{m - 1}^{( ℓ - α )} ] , ℓ = max ( 0 , ⌈ α ⌉ ) & ( 4 )\end{matrix}$$

The weight w included in Equation (4) is expressed by the following Equation (5). Further, Γ(ν) in Equation (5) is a gamma function.

$$\begin{matrix}[ Equation 5 ] & \\ {( {w}_{k}^{( v )} )}_{i} = \{ \begin{matrix}{( {t}_{k} - {t}_{i} )}^{v - 1} / Γ ( v ) & ( i < k ) \\ 0 & ( i \geq k )\end{matrix} & ( 5 )\end{matrix}$$

The transformation D^{(α)} of the fractional differential equation expressed by Equation (4) can be calculated on the left side of Equation (3) because the values of the respective components of the matrix are determined when the differential order α is determined. The information processing system according to the present embodiment performs processing of using the differential order α of the fractional differential equation as the first parameter and using the coefficients A and B on the right side of Equation (3) as the second parameters, to calculate the parameters of these models using the dynamic mode decomposition.

The above equation describes an example of the method of implementing the fractional differential equation, and the implementation method is not limited to the one expressed by the above equation. For example, an implementation method using a high-order difference method may be adopted, or for example, an implementation method using integration of a non-integer order may be adopted, and similar effects can also be expected when these implementation methods are adopted. Further, various mounting methods other than these methods may be adopted.

### Parameter Calculation Processing

In the information processing system according to the present embodiment, a plurality of candidate values are prepared in advance for the differential order α that is the first parameter. The candidate values for the first parameter are set in advance by, for example, the user, an administrator, a designer, or the like of the information processing system according to the present embodiment, and stored as setting files or the like in the storage unit 12 of the information processing apparatus 1. The setting of the candidate value may be performed by enumerating the candidate values as illustrated in, for example, “α=1.00, 1.01, 1.02, . . . , 1.99”, may be performed by, for example, setting of conditions such as “minimum value 1.00, maximum value 1.99, interval 0.01”, or may be performed by various methods other than these methods.

The information processing apparatus 1 acquires one candidate value from among the plurality of candidate values of the differential order α that is the first parameter. The information processing apparatus 1 calculates the value on the left side of Equation (3), that is, the time evolution data, based on the acquired candidate value of the differential order α, the above Equations (4) and (5), and the time series observed temperature data stored in the process DB 12b. The value calculated at this time is used as the correct answer value for the time evolution data.

After calculating the value on the left side of Equation (3), the information processing apparatus 1 performs the dynamic mode decomposition with control input using the time series control input data and observed temperature data stored in the process DB 12b. With this configuration, the information processing apparatus 1 can calculate the second parameter included in the right side of Equation (3), that is, the values of the matrices A and B.

Next, the information processing apparatus 1 calculates the prediction value of the time evolution data by performing the calculation on the right side of Equation (3) in which the calculated A and B are set, with respect to the time series control input data and observed temperature data stored in the process DB 12b. The information processing apparatus 1 calculates the error (for example, mean square error or average absolute error) between the calculated correct answer value and the calculated prediction value of the time evolution data. With this configuration, the information processing apparatus 1 can obtain the second parameters A and B and the prediction error with respect to one candidate value of the first parameter α.

The information processing apparatus 1 performs the same processing with respect to the plurality of candidate values of the set first parameter α, to calculate the second parameters A and B and the error with respect to the candidate values of all the first parameters α. The information processing apparatus 1 compares all the calculated errors to acquire the first parameter α and the second parameters A and B associated with the minimum error, and outputs these acquired parameters as the calculation results of the parameters of the model.

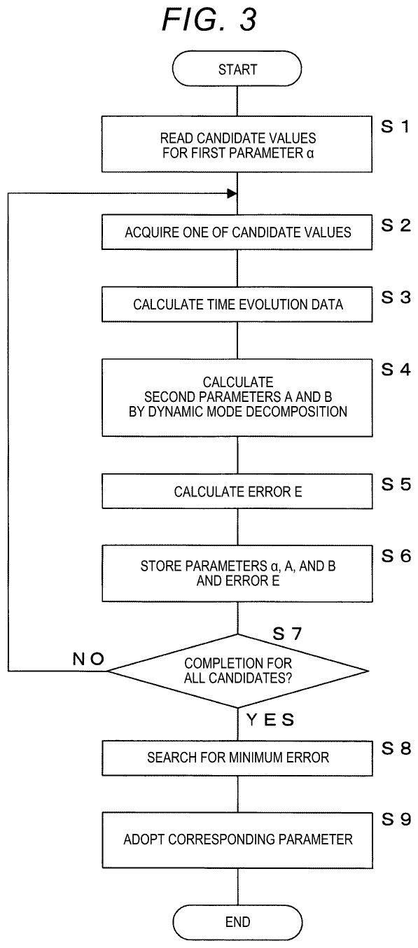

FIG. 3 is a flowchart illustrating a procedure of parameter calculation processing performed by the information processing apparatus 1 according to the present embodiment. The parameter calculation unit 11c of the processor 11 of the information processing apparatus 1 according to the present embodiment reads the plurality of candidate values of the first parameter α created in advance and stored in the storage unit 12 (step S1).

The parameter calculation unit 11c acquires one candidate value from among the plurality of candidate values of the first parameter α read in step S1 (step S2). The parameter calculation unit 11c calculates the time evolution data of the observed temperature data based on the fractional differential equation in which the first parameter α acquired in step S2 is set, and the time series observed temperature data stored in the process DB 12b (step S3).

The parameter calculation unit 11c calculates the second parameters A and B by performing the dynamic mode decomposition with control input based on the time evolution data calculated in step S3 and the time series control input data and observed temperature data stored in the process DB 12b (step S4).

The parameter calculation unit 11c calculates the prediction value of the time evolution data by performing the calculation on the right side of Equation (3) based on the second parameters A and B calculated in step S4 and the time series control input data and observed temperature data stored in the process DB 12b. The parameter calculation unit 11c calculates an error E between the calculated prediction value of the time evolution data and the correct answer value of the time evolution data calculated in step S3 (step S5). The parameter calculation unit 11c stores the candidate values of the first parameter α acquired in step S2, the second parameters A and B calculated in step S4, and the error E calculated in step S5, in association with each other in the storage unit 12 (step S6).

The parameter calculation unit 11c determines whether the processing of steps S2 to S6 has been completed for all the candidate values read in step S1 (step S7). When the processing has not been completed for all the candidate values (S7: NO), the parameter calculation unit 11c returns the processing to step S2, acquires another candidate value, and performs the processing of S2 to S6.

When the processing has been completed for all the candidate values (S7: YES), the parameter calculation unit 11c searches for the minimum error among a plurality of errors E calculated in step S5 with respect to each candidate value (step S8). The parameter calculation unit 11c adopts the first parameter α and the second parameters A and B corresponding to the minimum error E searched for in step S8 as the parameters of the model (step S9), and ends the processing.

The time evolution model expressed by Equation (3) is determined by the parameters calculated by the information processing apparatus 1. By using this time evolution model, various types of processing such as the prediction of the operation of the substrate processing apparatus 3, the control of the operation of the substrate processing apparatus 3, or the abnormality determination of the substrate processing apparatus 3 can be expected.

### Abnormality Determination Processing

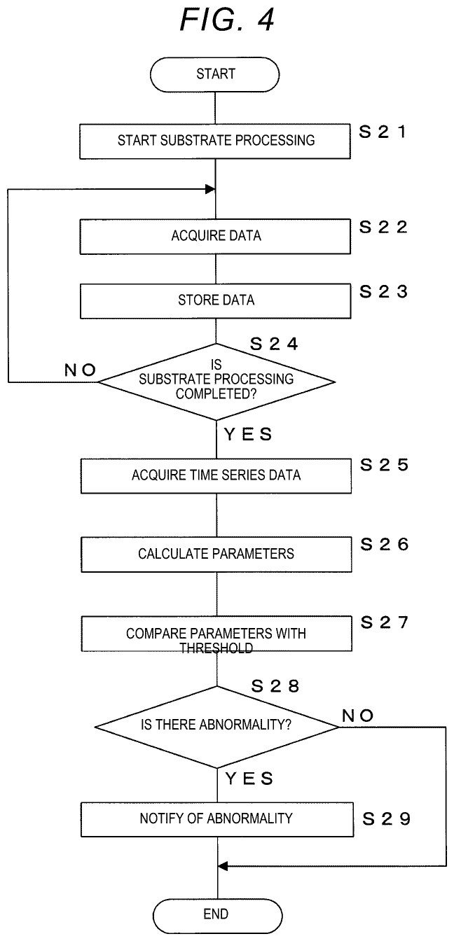

FIG. 4 is a flowchart illustrating a procedure of abnormality determination processing performed by the information processing apparatus 1 according to the present embodiment. The control processor 11a of the processor 11 of the information processing apparatus 1 according to the present embodiment starts the substrate processing such as etching on the wafer when receiving an operation for starting the processing by the user, for example (step S21).

The data acquisition unit 11b of the processor 11 acquires the control input data input to the substrate processing apparatus 3 and the observed temperature data observed by the sensors of the substrate processing apparatus 3 (step S22). The data acquisition unit 11b stores the control input data and observed temperature data acquired in step S22 and information such as the date and time of acquisition of the data and the identification information of the wafer that is the processing target, in association with each other in the process DB 12b (step S23).

The data acquisition unit 11b determines whether the substrate processing being performed on the wafer has been completed (step S24). When the substrate processing has not been completed (S24: NO), the data acquisition unit 11b returns the processing to step S22, and repeats the acquisition and storage of data.

When the substrate processing is completed (step S24: YES), the data acquisition unit 11b reads and acquires the time series control input data and observed temperature data stored in the process DB 12b in a period from the start to the end of the substrate processing on the wafer (step S25).

The parameter calculation unit 11c of the processor 11 calculates the parameters of the model using the dynamic mode decomposition based on the information on the candidate values of the differential order α prepared in advance, and the time series control input data and observed temperature data acquired in step S25 (step S26). The processing performed in step S26 corresponds to the parameter calculation processing illustrated in the flowchart of FIG. 3.

The abnormality determination unit 11d of the processor 11 compares the parameters of the model calculated in step S26 with a predetermined threshold (step S27). The abnormality determination unit 11d determines the presence or absence of the abnormality in the substrate processing performed this time, based on the comparison between the parameters of the model and the threshold (step S28). When there is the abnormality (S28: YES), the display processor 11e of the processor 11 notifies the user of the abnormality by displaying a message or the like indicating the detection of the abnormality on the display unit 14 (step S29), and ends the processing. Additionally, when there is the abnormality (S28: YES), another substrate processing operation (S21) can be started, for example, automatically. Step S29 can include corrective actions like adjusting control inputs of the substrate processing apparatus to fix the abnormality/issue. When there is no abnormality (S28: NO), the processor 11 ends the processing.

Modification Examples

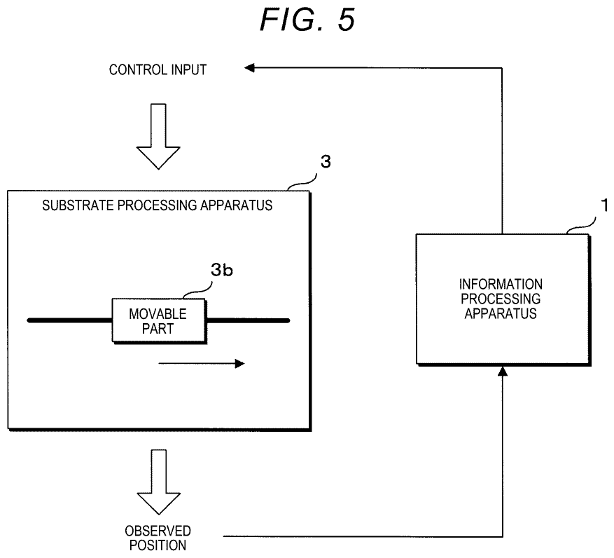

In the above-described embodiment, the temperature control of the substrate processing apparatus 3 has been described as an example, but the application of the present technology is not limited to the temperature control. FIG. 5 is a schematic diagram illustrating an overview of an information processing system according to a modification example. The information processing system according to the modification example is, for example, a system that performs the abnormality determination or the like on the substrate processing apparatus 3 that is configured to transfer the wafer. In addition to determining the presence or absence of abnormalities as described above, the information processing system according to the present embodiment may further include functionality to correct detected abnormalities in the operation of the substrate processing apparatus 3. This correction process leverages the parameters calculated by the parameter calculation unit 11c and the abnormality determination results from the abnormality determination unit 11d to dynamically adjust the control input data supplied to the target apparatus, thereby mitigating deviations from normal operation and enhancing processing reliability. The correction process begins after the abnormality determination unit 11d identifies an abnormality by comparing the calculated first parameter (e.g., differential order α) and second parameters (e.g., coefficients A and B) against predetermined thresholds or

a pre-trained abnormality determination model, as described in paragraph [0036]. Upon detecting an abnormality, the control processor 11a retrieves the time evolution model defined by Equation (3), parameterized with the calculated first and second parameters, and uses it to simulate potential adjustments to the control input data. For example, in the context of temperature control, the control input data may include adjustments to the power supplied to the heater or the flow rate of the chiller, while in the context of wafer transfer. To determine the corrective action, the control processor 11a performs an optimization routine. Specifically, it iteratively adjusts the control input vector Y=[u(t0), u(t1), . . . , u(tm−1)] within predefined operational constraints (e.g., maximum allowable temperature or actuator speed) and recalculates the predicted time evolution data π(x)(t) using Equation (3). The goal is to minimize the deviation between the predicted time evolution data and a reference time evolution profile, which is derived from the parameters of the model calculated using data collected during normal operation (e.g., stored in the model information storage unit 12c). The optimization may employ techniques such as gradient descent or constrained least squares, ensuring that the adjusted control input data restores the observed data x(t) to within an acceptable range of normal behavior. Once the optimal control input adjustments are determined, the control processor 11a transmits the updated control input data to the substrate processing apparatus 3 via the communication unit 13. The data acquisition unit 11b then monitors the subsequent observed data (e.g., temperature or position data) to verify the effectiveness of the correction. If the observed data converges toward the reference profile within a predetermined time window (e.g., a few sampling intervals), the correction is deemed successful, and the process resumes normal monitoring. If the abnormality persists, the system may escalate the response by notifying the user through the display processor 11e (as in paragraph [0038]) while continuing to refine the control input adjustments, or it may halt the apparatus operation to prevent damage, depending on the severity of the abnormality as predefined in the system settings.

The substrate processing apparatus 3 according to the modification example includes a transfer mechanism that transfers the wafer. The transfer mechanism includes a movable part 3b that moves in response to an operation of, for example, an actuator or a motor. The substrate processing apparatus 3 drives the actuator, the motor, or the like in accordance with the control input data from the information processing apparatus 1, and the movable part 3b moves in response thereto to transfer the wafer.

Further, the substrate processing apparatus 3 includes a sensor or the like that measures a position. The information processing apparatus 1 acquires a measurement result of the position of the movable part 3b by the sensor of the substrate processing apparatus 3 as the observed position data at predetermined intervals. In the present modification example, the sensor measures the position of the movable part 3b, but the present disclosure is not limited to this configuration, and the sensor may measure, for example, the speed, the acceleration, or the like of the movable part 3b. Further, in a case where the movable part 3b is a part that rotates, for example, the rotation speed, the angular velocity, or the like may be measured by the sensor. Further, the information processing apparatus 1 may acquire video data of the movable part 3b captured by a camera, instead of the sensor. Further, the information processing apparatus 1 may acquire a combination of the plurality of pieces of information.

The information processing apparatus 1 acquires the control input data and the observed position data at predetermined intervals, and stores the acquired control input data and observed position data in the process DB 12b. After the transfer of the wafer by the substrate processing apparatus 3 is completed, the information processing apparatus 1 can calculate the parameters of the model in accordance with the procedure described above based on the time series control input data and observed position data stored in the process DB 12b, and perform processing such as the abnormality determination based on the calculated parameters.

Further, the application of the present technology is not limited to the temperature control and the wafer transfer control. The present technology can be applied to control relating directly or indirectly to a state of the substrate processing apparatus 3.

### Modification Example 2

The information processing system described above adopts the fractional differential equation illustrated in Equation (4) as the transformation π, but the transformation π is not limited to the non-integer order. Any transformation can be adopted as the transformation function as long as the transformation satisfies the causality. As the transformation function, various functions may be used, such as a function expressing a hysteresis effect of a target system, an exponential function, a logarithmic function, a polynomial, a trigonometric function, a function defined for each segment, a function generated by summing or multiplying these functions, and a function generated through machine learning, such as a neural network or the like, which are determined experimentally or theoretically. Further, the transformation function may be determined probabilistically, for example, by giving the transformed value by a probability distribution.

In Modification Example 2, a method will be described in which the transformation functions expressed by the matrix D_{π} illustrated in the following Equation (6) are adopted as an example of various transformation functions, and the information processing system optimizes the values a and b included in the matrix D_{π} using the time series observed temperature data. D_{π} of the transformation function of Equation (6) is an example and is not limited thereto. For example, D_{π} may be independent of all components, or may be limited to a matrix in which the same values are aligned from the upper left to the lower right, for example.

$$\begin{matrix}[ Equation 6 ] & \\ {D}_{n} ( a , b ) = [ \begin{matrix}a & b & & & 0 \\ & a & ⋱ & & \\ & & ⋱ & b & \\ & & & a & b \\ 0 & & & & a\end{matrix} ] & ( 6 )\end{matrix}$$

The information processing apparatus 1 according to Modification Example 2 sets appropriate initial values for the matrix D_{π} of the transformation functions, and calculates the coefficients A and B in Equation (3) by the method of the dynamic mode decomposition based on the above Equations (1) to (3). Then, the information processing apparatus 1 calculates the left side and the right side of Equation (3) using the time series observed temperature data and control input data, calculates the error, and updates the matrix D_{π} by using, for example, the existing steepest descent method or the like based on the error. The information processing apparatus 1 can ultimately optimize the components a and b of the D_{π} by repeating the above-described processing to update the matrix D_{π} such that the calculated error falls within a desired range.

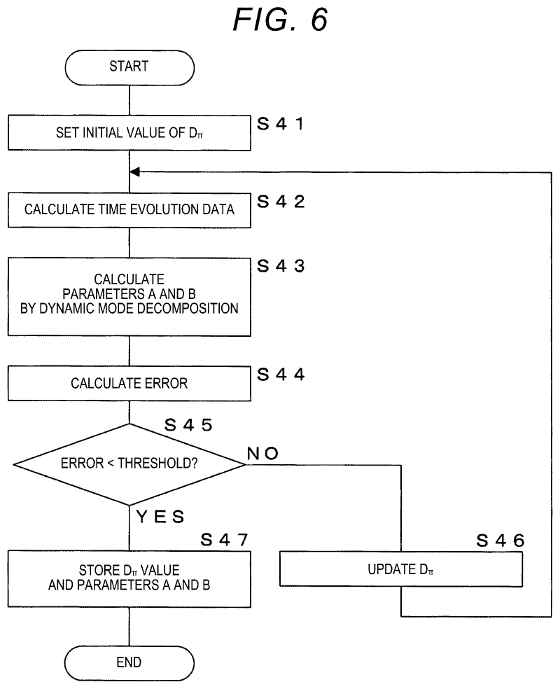

FIG. 6 is a flowchart illustrating a procedure of parameter calculation processing performed by an information processing apparatus 1 according to Modification Example 2. The parameter calculation unit 11c of the processor 11 of the information processing apparatus 1 according to Modification Example 2 sets appropriate initial values for the components a and b of the matrix D_{π} of the transformation function (step S41). The initial values of a and b may be, for example, values determined in advance by the user, may be values based on, for example, random numbers, or may be values determined by other methods.

The parameter calculation unit 11c calculates the time evolution data of the observed temperature data based on the matrix D_{π} set in step S1 and the time series observed temperature data stored in the process DB 12b (step S42). The parameter calculation unit 11c calculates the parameters A and B by performing the dynamic mode decomposition with control input based on the above Equation (3) using the time evolution data calculated in step S42 and the time series control input data and observed temperature data stored in the process DB 12b (step S43).

The parameter calculation unit 11c calculates the prediction value of the time evolution data by performing the calculation on the right side of Equation (3) based on the parameters A and B calculated in step S43 and the time series control input data and observed temperature data stored in the process DB 12b. The parameter calculation unit 11c calculates the error between the calculated prediction value of the time evolution data and the time evolution data calculated in step S42 (step S44).

The parameter calculation unit 11c determines whether the error calculated in step S44 is smaller than a predetermined threshold (step S45). When the error is equal to or greater than the threshold (S45: NO), the parameter calculation unit 11c updates the values of the components a and b of the matrix D_{π} such that the error becomes smaller by, for example, a method such as the steepest descent method based on the differential of the error calculated in step S44 (step S46), and returns the processing to step S42 to repeat the processing described above.

When the error is smaller than the threshold (S45: YES), the parameter calculation unit 11c sets the components a and b and the parameters A and B of the matrix D_{π} at this point in time as the optimum values, stores these values in the storage unit 12 (step S47), and ends the processing.

When the matrix D_{π} is updated, the sum or average value of errors or the like calculated for a plurality of pieces of time series data may be used. For example, when there are a plurality of pieces of time series data that are expected to be described by the same matrix Dπ, but may have different coefficient matrices A and B, the error calculated in step S44 of the flowchart illustrated in FIG. 6 may be calculated using functions such as the sum or average value of errors when the optimum coefficient matrices A and B are used for these pieces of time series data. Further, the same applies to a case where the coefficient matrices A and B have the same value between the plurality of pieces of time series data.

In addition, in step S44 of the flowchart illustrated in FIG. 6, the information processing apparatus 1 according to Modification Example 2 described above calculates the time evolution data based on the left side of Equation (3) using the matrix D_{π}, and the prediction value of the time evolution data based on the right side of Equation (3) using the calculated parameters A and B, thereby calculating the error in both pieces of time evolution data. However, the information processing apparatus 1 can perform the calculation directly from the parameters A and B without calculating the prediction value of the time evolution data using the calculated parameters A and B.

When all the components of the matrix of the parameters A and B are arranged in order and vectorized to be θ (see the following Equation (7)), an error L(θ) to be calculated is as expressed by Equation (8). In Equation (8), the right side is the Frobenius norm of the matrix. Further, π(x) is the time evolution data calculated based on the matrix D_{π} and the observed data X.

$$\begin{matrix}[ Equation 7 ] & \\ θ = [ {A}_{11} , {A}_{12} , … , {B}_{11} , {B}_{12} , … ] & ( 7 )\end{matrix}$$

$$L ( θ ) = {\sum }_{i} {\vert π ( x ) ( {t}_{i} ) - Ax ( {t}_{i} ) - Bu ( {t}_{i} ) \vert}^{2} = {‖ {XD}_{π} - AX - B Υ ‖}_{F}^{2} \qquad ( 8 )$$

With respect to the error L(θ) determined by Equation (8), the information processing apparatus 1 calculates a constant term c, a first-order derivative J, and a second-order derivative H of the error illustrated in the following Equations (9) to (11).

$$\begin{matrix}[ Equation 8 ] & \\ c = L ( θ ) & ( 9 )\end{matrix}$$

$$J = \frac{\partial L}{\partial θ} {\vert}_{θ} \qquad ( 10 )$$

$$H = \frac{{\partial }^{2} L}{\partial {θ}^{2}} \qquad ( 11 )$$

By performing calculation of the following Equation (12) based on the calculated constant c, first-order derivative J, and second-order derivative H, the information processing apparatus 1 can calculate the minimum error L* obtained when only the parameters A and B are optimized while fixing the matrix D_{π}. In Equation (12), superscript “T” expresses a transposed matrix, and superscript “+” expresses a general inverse matrix.

$$\begin{matrix}[ Equation 9 ] & \\ {L}_{*} = c - \frac{{J}^{T} {H}^{+} J}{2} & ( 12 )\end{matrix}$$

In step S44 of the flowchart illustrated in FIG. 6, the information processing apparatus 1 calculates the error L* based on Equation (12), and can update the matrix D_{π} in step S46 using the calculated L*.

### Summary

In the information processing system according to the present embodiment configured as described above, the information processing apparatus 1 acquires the time series observed temperature data relating to the substrate processing apparatus 3 as the target apparatus, and calculates the first parameter and the second parameter of the model that predicts the time evolution data of the observed data based on the observed data, by the dynamic mode decomposition based on the acquired observed temperature data. The first parameter of the model can be the parameter D_{π} of the function for transforming the observed temperature data into the time evolution data. The second parameter of the model can be the parameter A relating to the function of the observed data describing the time evolution data. With this configuration, the information processing system can be expected to generalize the dynamic mode decomposition to generate a more accurate model, and can be expected to effectively utilize the data obtained from the substrate processing apparatus 3.

In the information processing system according to the present embodiment, the function for transforming the observed temperature data into the time evolution data is a function expressed by the fractional differential equation, and the first parameter includes the differential order α of the fractional differential equation. With this configuration, the information processing system can determine the transformation function by setting the differential order α, so that the number of parameters to be calculated can be expected to be reduced.

In the present embodiment, the fractional differential equation is adopted as the transformation function, but the present disclosure is not limited thereto. As the transformation function, various functions may be used, such as an exponential function, a logarithmic function, a polynomial, a trigonometric function, a function defined for each segment, a Gaussian distribution having a specific positive value as an average of a specific time difference in the distribution, a function generated by summation or product thereof, or a function generated through machine learning or the like.

The embodiments disclosed herein are exemplary in all respects and can be considered to be not restrictive. The scope of the present disclosure is indicated by the claims, not the above-described meaning, and is intended to include all modifications within the meaning and scope equivalent to the claims.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

1. An information processing method performed by an information processing apparatus, the information processing method comprising:
acquiring time series observed data regarding a target apparatus;
calculating a first parameter and a second parameter of a model that predicts time evolution data of the observed data based on the observed data, by dynamic mode decomposition based on the acquired observed data; and
correcting an abnormality in the target apparatus by adjusting control input data for the target apparatus based on the calculated first and second parameters and the predicted time evolution data,
wherein the first parameter is a parameter relating to a transformation function for transforming the observed data into the time evolution data, and
the second parameter is a parameter relating to a function of the observed data describing the time evolution data.

2. The information processing method according to claim 1,
wherein the transformation function is a function expressed by a fractional differential equation, and
the first parameter includes an order of the fractional differential equation.

3. The information processing method according to claim 1, further comprising:
acquiring the time series control input data for the target apparatus and the observed data corresponding to the control input data; and
calculating the first parameter and the second parameter of the model by dynamic mode decomposition based on the acquired control input data and observed data,
wherein the second parameter is a parameter relating to functions of the control input data and the observed data describing the time evolution data.

4. The information processing method according to claim 3,
wherein the second parameter includes a coefficient matrix for the control input data and a coefficient matrix for the observed data.

5. The information processing method according to claim 3, further comprising:
acquiring a plurality of candidate parameters relating to the first parameter;
calculating the second parameter corresponding to each candidate parameter of the first parameter by dynamic mode decomposition based on the acquired control input data and observed data, respectively;
performing a prediction using the model for each set of the candidate parameter of the first parameter and the corresponding second parameter, to calculate a prediction value for each candidate parameter;
calculating the time evolution data based on the acquired observed data; and
determining the first parameter from the plurality of candidate parameters based on an error between the prediction value of the time evolution data for each candidate parameter and the time evolution data calculated based on the observed data.

6. The information processing method according to claim 3,
wherein an initial value is set to the first parameter, and
the method further comprises:
calculating the second parameter corresponding to the first parameter to which the initial value is set by dynamic mode decomposition based on the acquired control input data and observed data, respectively;
calculating an error relating to the time evolution data output by the model based on the calculated second parameter; and
updating the first parameter based on the calculated error.

7. The information processing method according to claim 1,
wherein a state of the target apparatus is determined based on the calculated parameters.

8. The information processing method according to claim 3,
wherein the target apparatus is a substrate processing apparatus, and
the method further comprises acquiring time series control input data for the substrate processing apparatus and time series observed data obtained by sensors provided in the substrate processing apparatus.

9. A non-transitory computer-readable storage medium having computer-executable instructions stored thereon, which when executed by one or more processors, cause the one or more processors to execute a method comprising:
acquiring time series observed data regarding a target apparatus; and
calculating a first parameter and a second parameter of a model that predicts time evolution data of the observed data based on the observed data, by dynamic mode decomposition based on the acquired observed data; and
correcting an abnormality in the target apparatus by adjusting control input data for the target apparatus based on the calculated first and second parameters and the predicted time evolution data,
wherein the first parameter is a parameter relating to a transformation function for transforming the observed data into the time evolution data, and
the second parameter is a parameter relating to a function of the observed data describing the time evolution data.

10. The non-transitory computer-readable storage medium according to claim 9,
wherein the transformation function is a function expressed by a fractional differential equation, and
the first parameter includes an order of the fractional differential equation.

11. The non-transitory computer-readable storage medium according to claim 9, wherein the method further comprises:
acquiring the time series control input data for the target apparatus and the observed data corresponding to the control input data; and
calculating the first parameter and the second parameter of the model by dynamic mode decomposition based on the acquired control input data and observed data, and
the second parameter is a parameter relating to functions of the control input data and the observed data describing the time evolution data.

12. The non-transitory computer-readable storage medium according to claim 11,
wherein the second parameter includes a coefficient matrix for the control input data and a coefficient matrix for the observed data.

13. The non-transitory computer-readable storage medium according to claim 11,
wherein the target apparatus is a substrate processing apparatus, and
the method further comprises acquiring the time series control input data for the substrate processing apparatus and time series observed data obtained by sensors provided in the substrate processing apparatus.

14. The non-transitory computer-readable storage medium according to claim 9, wherein the method further comprises:
acquiring a plurality of candidate parameters relating to the first parameter;
calculating the second parameter corresponding to each candidate parameter of the first parameter by dynamic mode decomposition based on the acquired control input data and observed data, respectively;
performing a prediction using the model for each set of the candidate parameter of the first parameter and the corresponding second parameter, to calculate a prediction value for each candidate parameter;
calculating the time evolution data based on the acquired observed data; and
determining the first parameter from the plurality of candidate parameters based on an error between the prediction value of the time evolution data for each candidate parameter and the time evolution data calculated based on the observed data.

15. The non-transitory computer-readable storage medium according to claim 11,
wherein an initial value is set to the first parameter,
the method further comprises:
calculating the second parameter corresponding to the first parameter to which the initial value is set is calculated by dynamic mode decomposition based on the acquired control input data and observed data, respectively,
calculating an error relating to the time evolution data output by the model based on the calculated second parameter, and
updating the first parameter based on the calculated error.

16. The non-transitory computer-readable storage medium according to claim 9,
wherein a state of the target apparatus is determined based on the calculated parameters.

17. An information processing apparatus comprising:
a controller having a processor and a memory with a computer readable program stored therein that upon execution of the computer readable program by the processor configures the controller to:
acquire time series observed data regarding a target apparatus;
calculate a first parameter and a second parameter of a model that predicts time evolution data of the observed data based on the observed data, by dynamic mode decomposition based on the acquired observed data; and
correct an abnormality in the target apparatus by adjusting control input data for the target apparatus based on the calculated first and second parameters and the predicted time evolution data,
wherein the first parameter is a parameter relating to a transformation function for transforming the observed data into the time evolution data, and
the second parameter is a parameter relating to a function of the observed data describing the time evolution data.

18. The information processing apparatus according to claim 17,
wherein the transformation function is a function expressed by a fractional differential equation, and
the first parameter includes an order of the fractional differential equation.

19. The information processing apparatus according to claim 17,
wherein the controller is further configured to:
acquire time series control input data for the target apparatus and the observed data corresponding to the control input data; and
calculate the first parameter and the second parameter of the model by dynamic mode decomposition based on the acquired control input data and observed data, and
the second parameter is a parameter relating to functions of the control input data and the observed data describing the time evolution data.

20. The information processing apparatus according to claim 19,
wherein the controller is further configured to:
acquire a plurality of candidate parameters relating to the first parameter,
calculate the second parameter corresponding to each candidate parameter of the first parameter by dynamic mode decomposition based on the acquired control input data and observed data, respectively,
perform a prediction using the model for each set of the candidate parameter of the first parameter and the corresponding second parameter, to calculate a prediction value for each candidate parameter,
calculate the time evolution data based on the acquired observed data, and
determine the first parameter from the plurality of candidate parameters based on an error between the prediction value of the time evolution data for each candidate parameter and the time evolution data calculated based on the observed data.
